(19) United States
(12) Patent Application Publication
(10) Pub. No.: US 2026/0372211 A1
(43) Pub. Date: Nov. 19, 2026

(54) Superconducting Circuit Apparatus and Method of Fabrication the Same

(71) Applicant: NEC Corporation, Minato-ku, Tokyo (JP)

(72) Inventors: Ayami YAMAGUCHI, Tokyo (JP); Kenji NANBA, Tokyo (JP); Akira MIYATA, Tokyo (JP); Katsumi KIKUCHI, Tokyo (JP)

(73) Assignee: NEC Corporation, Minato-ku, tokyo (JP)

(21) Appl. No.: 18/614,869

(22) Filed: Mar. 25, 2024

(30) Foreign Application Priority Data
Mar. 29, 2023 (JP) 2023-053031

(51) Int. Cl. H10W 90/00; G06N 10/40; H10N 69/00; H10W 70/00; H10W 70/63

(52) U.S. Cl. CPC H10W 90/401; H10N 69/00; H10W 70/099; H10W 70/635; H10W 90/724; H10W 90/7295; G06N 10/40

(57) ABSTRACT

A superconducting circuit apparatus includes a second circuit substrate; a first circuit substrate mounted on the second circuit substrate; and a quantum device mounted on the first circuit substrate. A first transmission circuit section for receiving and/or outputting a signal from the second circuit substrate to the quantum device includes: a first bonding section between the second circuit substrate and the first circuit substrate; a through via of the first circuit substrate; a non-contact coupling circuit of the quantum device and a non-contact coupling circuit transmission part of the first circuit substrate, unified in a layout among first transmission circuit sections.

### CROSS REFERENCE TO RELATED APPLICATIONS

This application is based upon and claims the benefit of the priority of Japanese patent application No. 2023-053031, filed on Mar. 29, 2023, the disclosure of which is incorporated herein in its entirety by reference thereto.

The present invention relates to a superconducting circuit apparatus and a method of fabrication the same.

### FIELD

### Background

In order to implement a highly integrated superconducting quantum circuit, a use of a structure in which a quantum device is flip-chip mounted on a first circuit substrate (interposer) (a structure in which a bare chip is flipped and mounted thereon) is being studied. In particular, a structure in which a configuration of the first circuit substrate (interposer) is distributed to a second circuit substrate (package substrate) is expected promising to prevent degradation of characteristics of a quantum bit (qubit) and increase a wiring accommodation ratio. As one of concrete structures, for example, the first circuit substrate may function as a relay substrate for the quantum circuit, and the second circuit substrate may function as a substrate for wire routing. Regarding the above requirement, for example, a structure in which two types of bumps are formed on a backside of each substrate (e.g., cap wafer/circuit wafer) to be stacked and are bonded to an electrode on a frontside surface of each substrate is disclosed in Patent Literature (PTL) 1, where the two types of bumps include a bonding bump for height control (standoff bump) and a bonding bump (In bump) made of material such as indium (In) that can be plastically deformed easily.

[PTL 1] U.S. Pat. No. 9,836,699 B1

### SUMMARY

It is an object of the present disclosure to provide a superconducting circuit apparatus and a method of fabrication the same, each enabling to realize high quality electrical bonding between a first circuit substrate coupled with a non-contact coupling circuit of a quantum device and a second circuit substrate in the superconducting circuit apparatus with the quantum device, the first circuit substrate, and the second circuit substrate stacked.

A superconducting circuit apparatus of one aspect of the present disclosure includes a second circuit substrate, a first circuit substrate mounted on the second circuit substrate, and a quantum device mounted on the first circuit substrate, the quantum device including a non-contact coupling circuit.

The first circuit substrate includes a non-contact coupling circuit transmission part arranged spaced apart from and opposed to the non-contact coupling circuit of the quantum device, and a through via penetrating through the first circuit substrate.

The superconducting circuit apparatus includes a plurality of first transmission circuit sections.

Each first transmission circuit section is configured to receive and/or output a signal from the second circuit substrate to the quantum device.

Each first transmission circuit section includes a first bonding section at which the second circuit substrate and the first circuit substrate are bonded together, the through via penetrating through the first circuit substrate, the non-contact coupling circuit of the quantum device, and the non-contact coupling circuit transmission part of the first circuit substrate, wherein the first bonding section, the through via, the non-contact coupling circuit, and the non-contact coupling circuit transmission part in each first transmission circuit section, are unified in a layout among the plurality of first transmission circuit sections, respectively.

According to another aspect of the present disclosure, a fabrication method of the above-described superconducting circuit apparatus includes:
placing the second circuit substrate and the first circuit substrate on which the quantum device is mounted in a chamber, such that a second bonding bump that is arranged on the second circuit substrate and configures the first bonding section, and a second electrode arranged on the first circuit substrate are arranged in a direction that a bonding face of the second bonding bump and a bonding face of the second electrode faces each other, and performing evacuation;
activating a surface of the bonding face of the second bonding bump arranged on the second circuit substrate and the second electrode arranged on the first circuit substrate;
performing a position alignment with the second bonding bump arranged on the second circuit substrate and the second electrode arranged on the first circuit substrate,
bringing the second bonding bump into contact with the second electrode to be pressurized in a room temperature or a low temperature not more than a predetermined temperature, with a vacuum, or
bringing the second bonding bump into contact with the second electrode to be pressurized with ultrasonic waves applied at a low temperature under atmospheric condition.

According to the present disclosure, a superconducting circuit apparatus and a method of fabrication the same that can realize high quality electrical bonding between a first circuit substrate, which is coupled with a non-contact coupling circuit of a quantum device, and a second circuit substrate, in the superconducting circuit apparatus in which the quantum device, the first circuit substrate, and the second circuit substrate are stacked, can be provided.

### BRIEF DESCRIPTION OF DRAWINGS

FIG. 1 is a schematic cross-sectional view illustrating an example embodiment of the present disclosure.

FIG. 2 is a schematic plan view illustrating a quantum device of the example embodiment of the present disclosure.

FIG. 3A and FIG. 3B are schematic plan views illustrating a first circuit substrate of the example embodiment of the present disclosure.

FIG. 4 is a schematic plan view illustrating a second circuit substrate of the example embodiment of the present disclosure.

FIG. 5 is a schematic cross-sectional view illustrating the example embodiment of the present disclosure.

FIG. 6A to FIG. 6C are schematic cross-sectional views illustrating an example embodiment of fabrication processes of the present disclosure, and FIG. 6D is a schematic view illustrating surface activation.

FIG. 7 is a schematic cross-sectional view illustrating a variation of the example embodiment of the present disclosure.

FIG. 8 is a schematic cross-sectional view illustrating an other variation of the example embodiment of the present disclosure.

### EXAMPLE EMBODIMENTS

In the following description of examples, reference is made to the accompanying drawings which form a part hereof, and in which it is shown by way of illustration specific examples that can be practiced. It is to be understood that other examples can be used and structural changes can be made without departing from the scope of the disclosed examples. It is noted that in the disclosure, the expression “at least one of A and B” means A, B, or (A and B). The term expressed as “--(s)” includes both singular and/or plural form. Regarding a three-dimensional mounting package configured with a plurality of substrates including a first circuit substrate (interposer) on which a quantum device is mounted, the structure disclosed in PTL 1 allows to control a spacing between substrates to an arbitrary distance to bond a bump to an opposing electrode. However, this structure cannot maintain uniformity of bonding conditions between substrates. This is because an energy applied during bonding, such as heating, loading, and ultrasonic wave is not-uniform among bonding sections due to lack of uniformity in a layout of the bonding section of each substrate. Therefore, a quality of bonding between substrates may not be ensured, as a result of which stable signal transmission is made difficult.

The above issue is one example and the present disclosure is, as a matter of course, not only directed to the solution of the above issue. The present disclosure enables to realize high quality electrical bonding between a first circuit substrate, which is coupled with a non-contact coupling circuit of a quantum device, and a second circuit substrate, in the superconducting circuit apparatus with the quantum device, the first circuit substrate, and the second circuit substrate stacked.

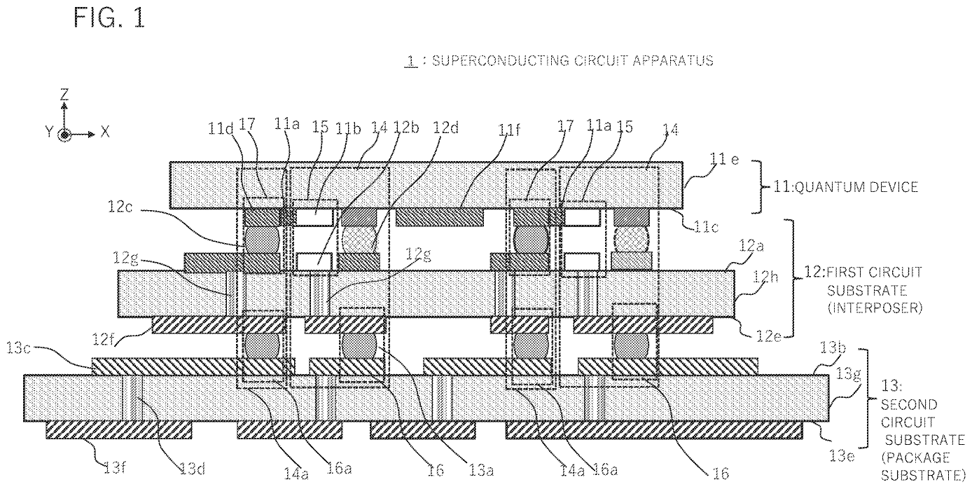

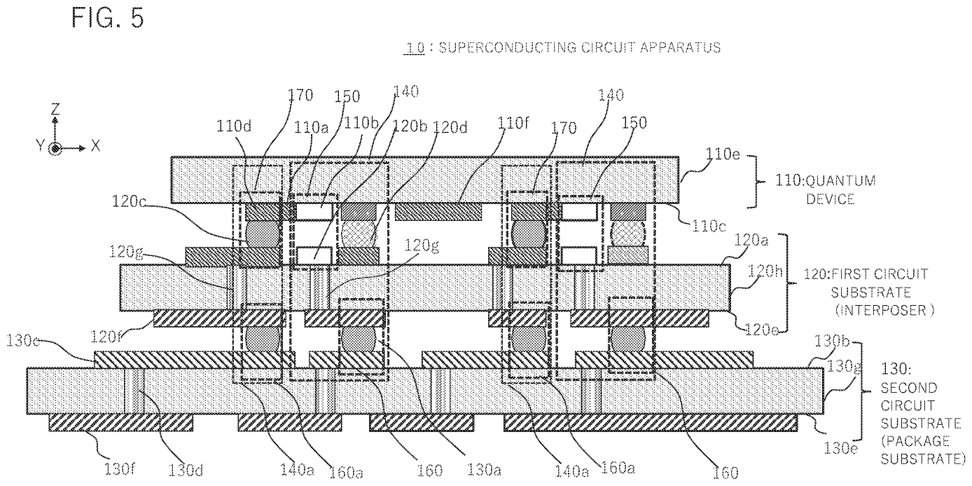

According to the present disclosure, in a superconducting circuit apparatus (for example 1 in FIGS. 1 and 10 in FIG. 5) in which a quantum device, a first circuit substrate and a second circuit substrate are stacked three-dimensionally,
a non-contact coupling circuit(s) (11b in FIG. 1, and 110b in FIG. 5) arranged on the quantum device (11 in FIGS. 1 and 110 in FIG. 5);
a non-contact coupling circuit transmission part(s) (12b in FIGS. 1 and 120b in FIG. 5) disposed on the first circuit substrate (12 in FIGS. 1 and 120 in FIG. 5) and arranged spaced apart from the non-contact coupling circuit of the quantum device and opposing thereto;
a through via(s) (12g in FIGS. 1 and 120g in FIG. 5) disposed in the first circuit substrate; and
a bonding section(s) (including a bonding bump connecting between the first circuit substrate and the second circuit substrate) (16 in FIGS. 1 and 160 in FIG. 5) of the second circuit substrate (13 in FIGS. 1 and 130 in FIG. 5) and the first circuit substrate,
configure a transmission circuit section(s) (14 in FIGS. 1 and 140 in FIG. 5) for receiving and/or outputting a signal from the second circuit substrate to the quantum device via the through via in the first circuit substrate.

According to the present disclosure, in the superconducting circuit apparatus including a plurality of the transmission circuit sections,
the bonding section between the second circuit substrate and the first circuit substrate;
the through via in the first circuit substrate; and
a transmission section (including the non-contact coupling circuit transmission part of the first circuit substrate and the non-contact coupling circuit of the quantum device) between the first circuit substrate and the quantum device,
of each transmission circuit section, are unified in a layout among the plurality of transmission circuit sections.

The above-described configuration ensures uniform propagation of heat and pressure, etc., when bonding the first circuit substrate on which the quantum device is mounted and the second circuit substrate, resulting in high bonding quality between the second circuit substrate and the first circuit substrate and reliable signal transmission.

According to the present disclosure, the bonding section between the first circuit substrate and the quantum device is disposed directly above the bonding section between the second circuit substrate and the first circuit substrate, which makes propagation of energy such as heat and/or pressure, suited to uniformity in bonding of the second circuit substrate and the first circuit substrate, thereby contributing to further enhancement of a bonding quality.

Furthermore, according to the present disclosure, as the transmission circuit section for receiving and/or outputting a signal from the second circuit substrate to the quantum device via the through via in the first circuit substrate, in a transmission circuit section(s) (second transmission circuit section(s)) (14a in FIGS. 1 and 140a in FIG. 5) other than the transmission circuit sections to the non-contact coupling circuit of the quantum device (14 in FIGS. 1 and 140 in FIG. 5),
a bonding section (16a in FIGS. 1 and 160a in FIG. 5) of the second circuit substrate and the first circuit substrate;
a through via (12g in FIGS. 1 and 120g in FIG. 5) in the first circuit substrate; and
a bonding section (17 in FIGS. 1 and 170 in FIG. 5) of the first circuit substrate and the quantum device,
of each second transmission circuit section, are unified in a layout among the plurality of second transmission circuit sections (14a in FIGS. 1 and 140a in FIG. 5), respectively.

According to the present disclosure, the above-described configuration makes it possible to improve and stabilize a connection quality in the bonding section between the second circuit substrate and the first circuit substrate.

FIG. 1 is a schematic cross-sectional view schematically illustrating an example of a cross-section of a superconducting circuit apparatus 1 of the present disclosure. Referring to FIG. 1, the superconducting circuit apparatus 1 includes a quantum device 11, a first circuit substrate 12, and a second circuit substrate 13. The first circuit substrate 12 may be termed an interposer and denoted as the first circuit substrate (interposer) 12. The second circuit substrate 13 maybe termed a package substrate and denoted as the second circuit substrate (package substrate) 13. As illustrated in FIG. 1, reference signs for identical elements are restricted to those necessary for explanation in order to avoid drawing from becoming complicated due to leading lines, etc.

The quantum device 11 includes a quantum circuit 11a, a non-contact coupling circuit 11b, a first electrode 11d, a circuit 11f, and a GND (ground) circuit (not shown) on a surface 11c of a chip base material (substrate) 11e. The GND circuit (not shown) may be a GND surface (GND plane) formed on the surface 11c of the chip base material 11e. As a non-limiting example, the circuit 11f may be a coupler connecting left and right quantum circuits 11a in FIG. 1. The quantum device 11 may be a chip (bare chip) fabricated using a semiconductor process. In this case, it is also called a quantum chip. The quantum device 11 is flip-chip mounted facing-down (the surface 11c on which the quantum circuit 11a and others are disposed is placed down) with respect to the first circuit substrate 12.

The first circuit substrate 12 includes a non-contact coupling circuit transmission part 12b, a first bonding bump 12c and a dummy bump 12d on a surface (first surface) 12a facing the surface 11c of the chip base material (substrate) 11e of the quantum device 11. The non-contact coupling circuit transmission part 12b is arranged spaced apart from the non-contact coupling circuit 11b of the quantum circuit 11a and opposing thereto. The dummy bump 12d may be a bonding bump (GND circuit bump) connected to a GND circuit. The GND circuit bump may be configured to connect to the GND circuit (not shown) on the surface 11c of the quantum device 11 or a GND circuit (not shown) on the first surface 12a of the first circuit substrate 12. In case the dummy bump 12d is not the GND circuit bump, it may be an isolated island-shaped one to which a circuit and/or a wiring are not connected on the surface 11c of the quantum device 11. The dummy bump 12d may not be necessarily provided.

The first circuit substrate 12 includes a second electrode 12f on a surface (second surface) 12e facing the second circuit substrate 13.

In the first circuit substrate 12, a through via 12g is disposed. The through via 12g penetrates through a base material (substrate) 12h of the first circuit substrate 12 and provides electrical connection between a wiring (electrode) of a first surface 12a and a wiring (electrode) of a second surface 12e.

In FIG. 1, the dummy bump 12d is illustrated using a pattern different from the first bonding bump 12c to make the dummy bump 12d explicit on the drawing. The dummy bump 12d may have the same structure (same conductive material, same dimensions) as the first bonding bump 12c. Also, the first electrode 11d bonded to the dummy bump 12d is illustrated with the different pattern from the first electrode 11d bonded to the first bonding bump 12c to make the electrode bonded on the dummy bump 12d explicit on the drawing. These first electrodes 11d may be made of the same conductive material with the same film thickness.

The second circuit substrate 13 includes a second bonding bump 13a on a first surface 13b which faces the second surface 12e of the first circuit substrate 12. A through via 13d is provided in the second circuit substrate 13. The through via 13d penetrates a base material (substrate) 13g and connects a wiring (electrode 13c) on the first surface 13b with a wiring (electrode 13f) on a second surface 13e opposite to the first surface 13b.

The first bonding bump 12c on the first surface 12a of the first circuit substrate 12 and the first electrode 11d of the quantum device 11 are physically bonded in a state that the non-contact coupling circuit transmission part 12b on the first surface 12a of the first circuit substrate 12 is arranged opposing the non-contact coupling circuit 11b of the quantum device 11.

In the second circuit substrate 13 and the first circuit substrate 12 on which the quantum device 11 is mounted, the second bonding bump 13a is directly bonded to the second electrode 12f on the second surface 12e of the first circuit substrate 12. Thus, the non-contact coupling circuit 11b of the quantum device 11 is electrically connected to the second circuit substrate 13 via the non-contact coupling circuit transmission part 12b and the through via 12g of the first circuit substrate 12.

Each layout of the following circuit elements:
(a) a bonding section 16 of the first circuit substrate 12 and the second circuit substrate 13, where the bonding section 16 includes the second bonding bump 13a;
(b) a through via 12g of the first circuit substrate 12; and
(c) a transmission section 15 between the first circuit substrate 12 and the quantum device 11, where the transmission section 15 includes the non-contact coupling circuit transmission part 12b of the first circuit substrate 12 and the non-contact coupling circuit 11b of the quantum circuit 11a, is unified in each one of the transmission circuit sections 14. That is, in the layout of placement and wiring of the second circuit substrate 13, the first circuit substrate 12, and the quantum device 11, a position (relative position) of the through via 12g of the first circuit substrate 12; and a position (relative positions) of the transmission section 15 between the first circuit substrate 12 and the quantum device 11, for example, with the bonding section 16 between the second circuit substrate 13 and the first circuit substrate 12 on the two-dimensional plane, as a reference point, are identical or nearly identical between the left and right transmission circuit sections 14 in FIG. 1. Alternatively, a position of the bonding section 16 between the second circuit substrate 13 and the first circuit substrate 12 and a position of the through via 12g of the first circuit substrate 12, for example, with a position of the transmission section 15 between the first circuit substrate 12 and the quantum device 11 as a reference point, are identical or nearly identical in the left and right transmission circuit sections 14 in FIG. 11. Alternatively, a position of the bonding section 16 between the second circuit substrate 13 and the first circuit substrate 12 and a position of the transmission section 15 between the first circuit substrate 12 and the quantum device 11, with the position of the through via 12g of the first circuit substrate 12, as a reference point, are identical or nearly identical between the left and right transmission circuit sections 14 in FIG. 11.

Directly above the bonding section 16 of the second circuit substrate 13 and the first circuit substrate 12, a bonding section (which may be the dummy bump 12d) is disposed between the first circuit substrate 12 and the quantum device 11.

Furthermore, regarding a transmission circuit section for receiving and/or outputting a signal from the second circuit substrate 13 to the quantum device 11 via the through via 12g in the first circuit substrate 12, other than the transmission circuit section 14 to the non-contact coupling circuit 11b of the quantum device 11, as with the transmission circuit section to non-contact coupling circuit 11b of the quantum device 11,
(a) the bonding section 16a of the second circuit substrate 13 and the first circuit substrate 12;
(b) the through via 12g of the first circuit substrate 12; and
(d) a bonding section 17 of the first circuit substrate 12, which includes the first bonding bump 12c, and the quantum device 11, are unified in a layout among the transmission circuit sections 14a. That is, in the layout of placement and wiring of the second circuit substrate 13, the first circuit substrate 12, and the quantum device 11, a position (relative position) of the through vias 12g of the first circuit substrate 12 and a position (relative position) of the bonding sections 17 between the first circuit substrate 12 and the quantum device 11, with a position of the bonding section 16a between the second circuit substrate 13 and the first circuit substrate 12 on the two-dimensional plane, as a reference point, are identical or nearly identical in the left and right transmission circuit sections 14 in FIG. 1.

The following describes another example of a superconducting circuit apparatus 10, handling of which is easy as compared with the aforementioned example.

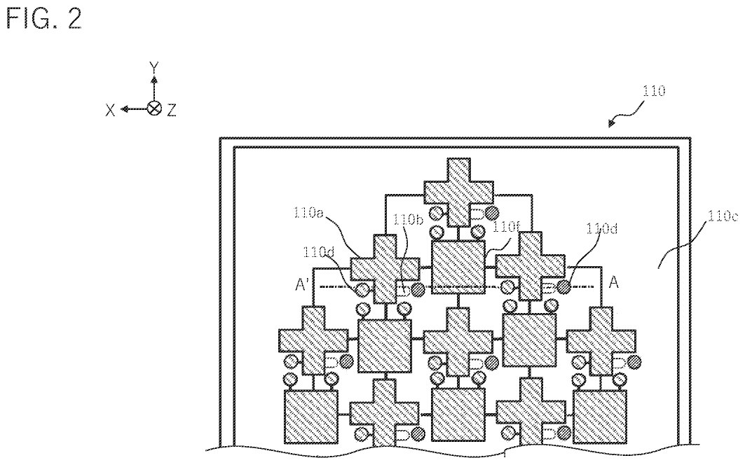

FIG. 2 is a schematic plan view illustrating a surface 110c (corresponding to 11c in FIG. 1) of a quantum device 110 used for the superconducting circuit apparatus 10. The quantum device 110 has a chip base material, and a first electrode 110d, a quantum circuit 110a, a non-contact coupling circuit 110b, a circuit 110f, and a GND circuit (not shown) made of superconducting material are formed on its surface 110c. The first electrode 110d, the quantum circuit 110a, the non-contact coupling circuit 110b, and the circuit 110f in FIG. 2 can correspond to the first electrode 11d, the quantum circuit 11a, the non-contact coupling circuit 11b, and the circuit 11f, respectively.

The first electrode 11d is connected to, for example, the quantum circuit 110a and a wiring (not shown). The quantum circuit 110a includes, for example, a quantum bit (qubit) using a Josephson junction. The non-contact coupling circuit 110b is connected to, for example, the quantum circuit 110a and a wiring (not shown). The non-contact coupling circuit 110b is, for example, a capacitive coupling circuit or an inductive coupling circuit, for non-contact capacitive or inductive coupling with a non-contact coupling circuit transmission part 120b on a first surface of a first circuit substrate 120 to receive and/or output a signal.

As a superconducting material, for example, niobium, niobium nitride, aluminum, indium, lead, tin, rhenium, palladium, titanium, titanium nitrides, tantalum, and an alloy containing at least one of the above metals may be used. For the chip base material (substrate), for example, silicon can be used.

In the quantum device 110 in FIG. 2, two electrodes disposed on an upper side of the circuit 110f with a rectangular shape may also be bonded to the first circuit substrate 120 with a bonding bump.

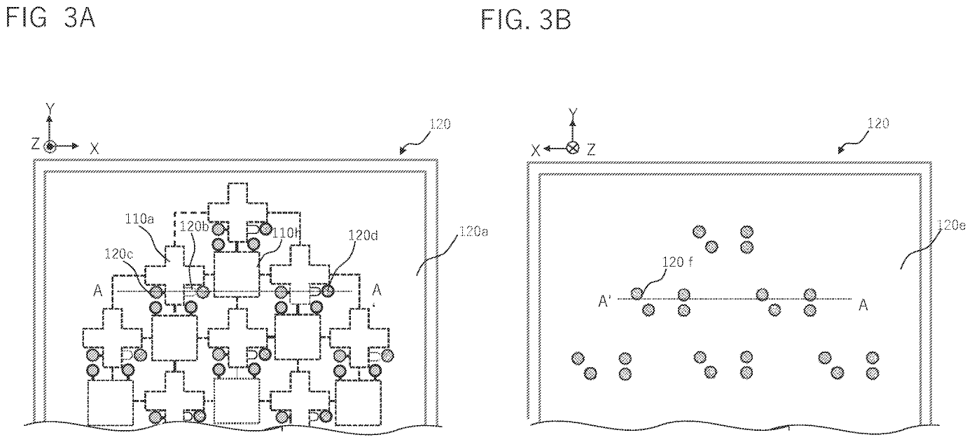

FIG. 3A is a schematic plan view illustrating a first surface 120a (corresponding to 12a in FIG. 1) of the first circuit substrate 120. The first circuit substrate 120 is also called an interposer and may be denoted as the first circuit substrate (interposer) 120. In FIG. 3A, the quantum circuit 110a (referring to FIG. 2) disposed on the surface 110c of the quantum device 110 that is arranged facing the first surface 120a is illustrated by a virtual line (dotted line.

A base material of the first circuit substrate 120 is preferably made of the same material (for example, silicon) as the chip base material (substrate) of the quantum device 110, in consideration of a linear expansion coefficient and so on. On the first surface 120a (corresponding to 12a in FIG. 1) of the first circuit substrate 120, the non-contact coupling circuit transmission part 120b, a first bonding bump 120c, and a dummy bump 120d are formed. The non-contact coupling circuit transmission part 120b, the first bonding bump 120c, and the dummy bump 120d in FIG. 3A can be corresponded to the non-contact coupling circuit transmission part 12b, the first bonding bump 12c, and the dummy bump 12d.

The dummy bump 120d has the same protrusion portion as the first bonding bump 120c. In the first circuit substrate 120, the dummy bump 120d is, for example, a floating island that is connected nowhere. Furthermore, the protrusion portion is disposed directly above a bonding section 160 of a second circuit substrate 130 and the first circuit substrate 120 and is preferably disposed in an area where interference and crosstalk are made smaller in terms of degradation of quantum circuit characteristics.

FIG. 3B is a schematic plan view illustrating a second surface 120e (12e in FIG. 1) of the first circuit substrate 120. On the second surface 120e of the first circuit substrate 120, which faces the second circuit substrate 130, a second electrode 120f (12f in FIG. 1) is formed. A through via (not shown) is formed in the first circuit substrate 120 which provide electrical connection between wiring of the first surface 120a and the second surface 120e of the first circuit substrate 120.

The bonding bump 120c (first bonding bump 12c in FIG. 1) has a protrusion portion with a predetermined height and a flat top surface. The protrusion portion may be made of a normal conductor such as copper (Cu) or an insulator (SiO2, silicon nitride film, silicon oxynitride film, etc.), whose surface-is coated with a superconducting film. A flatness of the protrusion portion, for example, may be preferably formed so that a roughness Ra (arithmetic average roughness) is 1 nm (nanometer) or less. A height of the protrusion portion is to be a height at which input/output characteristics of a designed signal can be obtained with non-contact coupling between the first circuit substrate 120 and the quantum device 110. Concrete values can be, for example, from 2 μm (micrometers) to 10 μm (micrometers) heigh. As a superconducting material, for example, niobium, niobium nitride, aluminum, indium, lead, tin, rhenium, palladium, titanium, titanium nitrides, tantalum, and an alloy containing at least one of the above metals may be used. The first bonding bump 120c is connected to a wiring layer (not shown) on the first surface 120a.

A top surface of the second electrode 120f may have a recess (concave-recess) of a predetermined depth. The second electrode 120f may be a superconducting material or a normal-conducting material. The second electrode 120f may, for example, have a configuration coated with a gold or the like, on a surface thereof. The second electrode 120f is, for example, connected to a wiring layer or through via (not shown).

A through via 120g, which penetrates through a substrate base material 120h of the first circuit substrate 120, is formed by drilling a hole in a wafer and filing a conductive material in the hole to form a through via electrode. The conductive material filled in an inner wall of the hole of the through via 120g can be either a superconducting material or a non-superconducting material (copper (Cu), nickel (Ni), gold (Au), platinum (Pt), etc.). In the first circuit substrate 120, the through via 120g is, for example, connected to the non-contact coupling circuit transmission part 120b and to a wiring layer (not shown) of the second surface 120e.

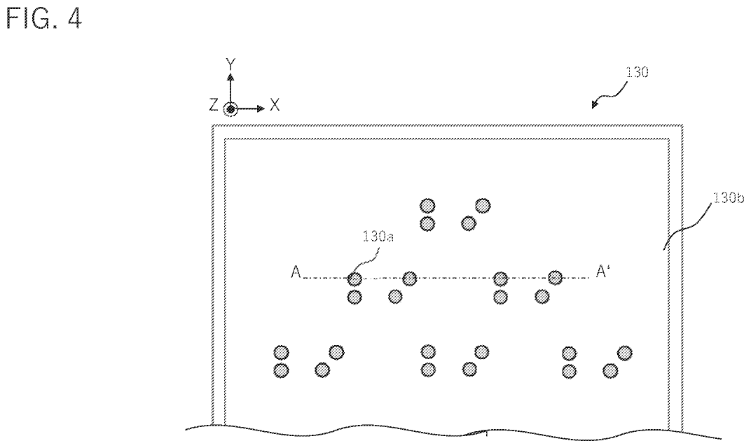

FIG. 4 is a schematic plan view illustrating a first surface 130b (corresponding to 13b in FIG. 1) of the second circuit substrate 130 used for a superconducting circuit apparatus 1. The second circuit substrate 130 is also called a package substrate and may be denoted as the second circuit substrate (package substrate) 130.

A base material of the second circuit substrate 130 is preferably made of the same material as a base material of the first circuit substrate 120, in consideration of a linear expansion coefficient and so on. The first circuit substrate 120 on which the quantum device 110 is flip-chip mounted and the second circuit substrate 130 on which the first circuit substrate 120 is mounted are made of materials with the same linear expansion coefficient, which allows suppression and mitigation of warpage, deformation, etc. caused by the difference between linear expansion coefficients of base materials (substrates) of the first circuit substrate 120 and the second circuit substrate 130 during a cooling process to an extremely low (cryogenic) temperature. On the first surface 130b, which faces the first circuit substrate 120, of the second circuit substrate 130, a second bonding bump 130a is formed. The second bonding bump 130a has a protrusion with a predetermined height. The protrusion may be made of a superconducting material with a low melting point and high ductility, such as indium (In), or a material equivalent to the first bonding bump 120c. The shape of the second bonding bump 130a may be dome-shaped, cylindrical, etc. The second bonding bump 130a is connected to a wiring layer (not shown) on the first surface 130b.

FIG. 5 is a schematic cross-sectional view illustrating a superconducting circuit apparatus 10 which is formed by bonding the first circuit substrate 120 on which the quantum device 110 is mounted and the second circuit substrate 130, and each substrate corresponds to a cross-sectional view of an A-A′ line of FIG. 2 to FIG. 4. The quantum device 110 is flip-chip (face-down) mounted on the first circuit substrate 120. The first bonding bump 120c and the first electrode 110d are physically bonded in a state that the non-contact coupling circuit transmission part 120b of the first circuit substrate 120 is arranged opposing the non-contact coupling circuit 110b of the quantum device 110 (transmission section 150 between the first circuit substrate 120 and the quantum device 110).

The second electrode 120f of the first circuit substrate 120 is formed by laminating a thin film of superconducting material or normal-conductive material on a wiring formed on the substrate base material 120h. This wiring portion can be formed using, for example, aluminum, copper, gold, platinum, and an alloy containing at least one of the above materials. The thin film may have a configuration coated with a gold or the like on the surface.

The second bonding bump 130a of the second circuit substrate 130 is formed on a multi-layer wiring formed on a substrate base material 130g, for example, as a protrusion made of material with a low melting point and high ductility. The protrusion is formed using, for example, an indium which is a superconducting material or a metal, such as gold, which is a normal-conducting material. By using a material with a low melting point and high ductility, such as indium, as the protrusion, the first circuit substrate 120 and the second circuit substrate 130 can be bonded at low bonding energy. Therefore, damage to a bonding section of the first circuit substrate 120 and the quantum device 110, which are bonded in advance, can be suppressed. A base substrate such as titanium, titanium nitride, indium, etc. may be added to ensure an adhesion strength of the wiring portion and the second bonding bump 130a. The protrusion may have a structure with a pillar made of copper, for example, at its bottom. This allows a height of a bonding section between the first circuit substrate 120 and the second circuit substrate 130 to be controlled to avoid an occurrence of a short circuit with an adjacent bonding bump. Furthermore, in the second bonding bump 130a, the wiring portion may be configured with a base substrate layer so as to enhance adhesion between the wiring portion and the substrate base material 130g.

The bonding section 160 between the second circuit substrate 130 and the first circuit substrate 120;
the through via 120g of the first circuit substrate 120; and
the transmission section 150 between the first circuit substrate 120 and the quantum device 110, of each transmission circuit section 140, are unified in a layout among transmission circuit sections 140 from the second circuit substrate 130 to non-contact coupling circuit 110b of the quantum device 110, respectively.

Directly above the bonding section 160 between the second circuit substrate 130 and the first circuit substrate 120, a bonding section (dummy bump 120d) is disposed between the first circuit substrate 120 and the quantum device 110.

Besides the transmission circuit section 140 from the second circuit substrate 130 to the non-contact coupling circuit 110b of the quantum device 110, regarding a transmission circuit section 140a configured with a bonding section 160a between the second circuit substrate 130 and the first circuit substrate 120;
the through via 120g of the first circuit substrate 120; and
a bonding section 170 between the first circuit substrate 120 including the first bonding bump 120c and the quantum device 110,
the bonding section 160a between the second circuit substrate 130 and the first circuit substrate 120;
the through via 120g of the first circuit substrate 120; and
the bonding section 170 between the first circuit substrate 120 and the quantum device 110 of each transmission circuit section 140a, are unified in a layout among transmission circuit sections 140a.

With the above configuration, an energy such as applied heat, pressure, etc. is uniformly and suitably propagated among a plurality of bonding sections in the bonding process described below.

The second bonding bump 130a of the second circuit substrate 130 and the second electrode 120f of the first circuit substrate 120 are bonded by making the surfaces thereof into contact with each other after activating the surfaces. This bonding technique is commonly known as a room temperature bonding.

In addition to the above bonding techniques, there are other bonding techniques such as ultrasonic and crimp bonding. With this bonding, the second bonding bump 130a with ductility follows a surface roughness of the second electrode 120f and is tightly bonded together in a state that an amorphous or alloy layer is formed at an interface, by respective materials that make up the second bonding bump 130a and the second electrode 120f. Therefore, a stable bonding condition can be obtained, ensuring high bonding quality.

In the above explanation, the bonding section disposed directly above the bonding section 160 between the second circuit substrate 130 and the first circuit substrate 120 is illustrated as the dummy bump 120d. However, it may be a bonding bump for a GND circuit connected to the GND circuit (not shown).

As long as the bonding section 160 between the second circuit substrate 130 and the first circuit substrate 120;
the through via 120g of the first circuit substrate 120; and
the transmission section 150 between the first circuit substrate 120 and the quantum device 110, of each transmission circuit section 140, are unified in a layout among transmission circuit sections 140, respectively, the dummy bump 120d may need not be disposed.

Present disclosure is not limited to a shape and arrangement of the bonding section (e.g., bonding bumps 120c and 120d) illustrated in FIG. 5. For example, a polygonal columnar shape, etc. can also be applied, and can be disposed at any position where designed operating characteristics of the quantum circuit 110a, the non-contact coupling circuit 110b, and the GND circuit can be obtained. The through via 120g illustrated in FIG. 5 is, as a matter of course, not limited to the arrangement illustrated in FIG. 5. For example, the through via 120g may also be disposed directly under the bonding bump (e.g., 120c), etc. A shape of each circuit is illustrated as a cross-shape and a square shape, but the shape is not limited to these shapes and can be any shape.

The following describes one of examples of a fabrication method of the superconducting circuit apparatus 10 described above.

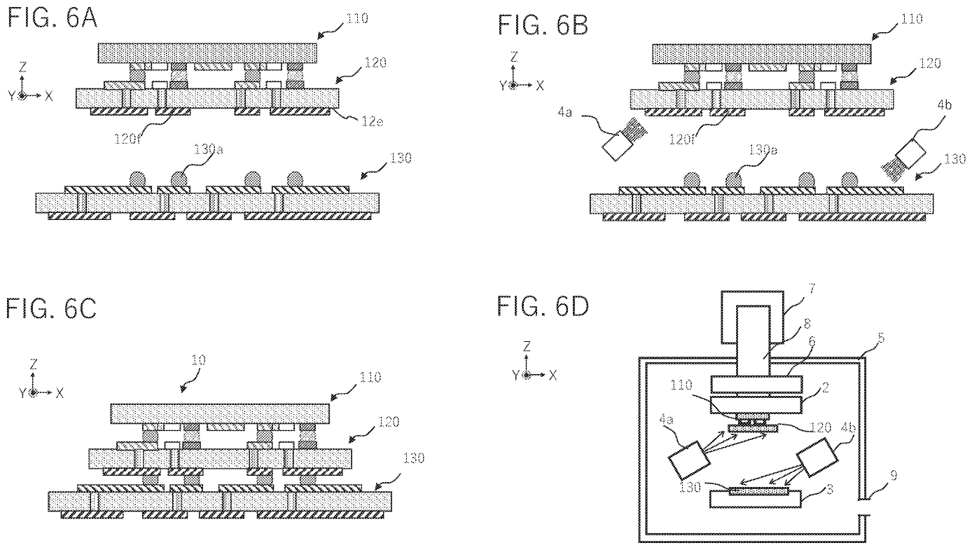

As illustrated in FIG. 6A, the first circuit substrate 120, on which the quantum device is mounted, and the second circuit substrate 130 are disposed in a vacuum chamber 5 with their bonding faces opposed to each other. Then as schematically illustrated in FIG. 6D, evacuation is performed from an evacuation port 9 by a vacuum pump (not shown). At this time, the first circuit substrate 120, on which the quantum device 110 is mounted, is fixed by a first fixing jig (stage) 2. A clamping method or an electrostatic chucking method can be applied as a fixing method. The second circuit substrate 130 is also fixed by a second fixing jig (state) 3. A clamping method or an electrostatic chucking method can be applied as a fixing method. For example, a degree of vacuum in the vacuum chamber 5 is preferably about 10⁻⁶ Pa (Pascal). A first fixing jig (holding member) 2 connects to a XY translation mechanism 6 and can be positioned with respect to the second fixing jig 3 on an underside by translating in the X and Y directions, moving in the Z direction, and rotating around the Z axis by means of the XY translation mechanism 6, a Z direction movement mechanism 7 and a Z-axis rotation mechanism 8.

Next, as illustrated in FIG. 6B, an activation device 4a is used to remove adsorbents and oxides on a surface of the second electrode 120f, which serves as a bonding section of the first circuit substrate 120, and to activate the bonding section. Similarly, an activation device 4b is used to remove adsorbents and oxides on a surface of the second bonding bump 130a, which is a bonding section of the second circuit substrate 130, and to activate the bonding section. As the activation devices 4a and 4b, for example, devices that irradiate ions or neutral atomic beams can be used, as illustrated in FIG. 6D.

Next, as illustrated in FIG. 6C, position alignment of the first circuit substrate 120 and the second circuit substrate 130 is performed so that the second electrode 120f faces the second bonding bump 130a. The position alignment is performed by translating the first fixing jig 2 in the X and Y directions and/or rotating around the Z axis relative to the second fixing jig 3 in FIG. 6D. While maintaining a degree of vacuum, the second electrode 120f and the second bonding bump 130a are made into contact and pressurized. Contact surfaces of the second electrode 120f of the first circuit substrate 120 and the second bonding bump 130a of the second circuit substrate 130 are made into contact with each other to be pressurized by the Z direction movement mechanism 7 in FIG. 6D. In this time, a pressure in a direction perpendicular to the contact surfaces under pressure may be measured by a Z-axis pressure sensor to control a pressure. A temperature may be, for example, a room temperature or a low temperature not more than 100 °C, for example. At this time, the second bonding bump 130a with ductility follows the surface roughness of the second electrode 120f. In a bonding interface between the second bonding bump 130a and the second electrode 120f, an amorphous layer is formed to fix them tightly.

For example, by providing an alignment mark (not shown) on each of the first circuit substrate 120 and the second circuit substrate 130 and adjusting their positions using a transmission image taken by an infrared camera (not shown in FIG. 6D), the position alignment thereof can be performed.

In FIG. 6B and FIG. 6D, a fabrication method of the superconducting circuit apparatus by a surface activation bonding is described, but bonding may be done by using methods such as ultrasonic waves (e.g., applying ultrasonic waves at a low temperature under atmospheric condition) or crimping etc.

According to the present disclosure, as illustrated in FIG. 5, in a superconducting circuit apparatus including a plurality of transmission circuit sections 140 for receiving and/or outputting a signal from the second circuit substrate 130 to the non-contact coupling circuit 110b of the quantum device 110 via the non-contact coupling circuit transmission part 120b of the first circuit substrate 120 and the through via 120g,
the bonding section 160 between the second circuit substrate 130 and the first circuit substrate 120;
the through via 120g of the first circuit substrate 120; and
the transmission section 150 between the first circuit substrate 120 and the quantum device 110 of each transmission circuit section 140, are unified in a layout in each transmission circuit section 140, respectively, which ensures uniform propagation of energy such as heat, pressure, etc., in bonding of the second circuit substrate 130 and the first circuit substrate 120, for example.

The bonding section (dummy bump) 120d between the first circuit substrate 120 and the quantum device 110 is disposed directly above the bonding section 160 between the second circuit substrate 130 and the first circuit substrate 120, which makes propagation of heat, pressure, etc. suitable when bonding the second circuit substrate and the first circuit substrate.

In addition to the above, regarding the transmission circuit section 140a for receiving and/or outputting a signal from the second circuit substrate 130 to the quantum device 110 via the through via 120g and the bonding section 170 (first bonding bump 120c) between the quantum device 110 and the first circuit substrate 120;
the bonding section 160a between the second circuit substrate 130 and the first circuit substrate 120;
the through via 120g of the first circuit substrate 120; and
the bonding section 170 between the first circuit substrate 120 and the quantum device 110 of each transmission circuit section 140a, are unified in a layout among transmission circuit sections 140a, respectively, which enables to improve a bonding quality (electrical connection quality) at least for the bonding section of the second circuit substrate 130 and the first circuit substrate 120. As a result, stable signal transmission between the second circuit substrate 130 and the first circuit substrate 120 can be ensured.

According to the fabrication method of the present example embodiment, by performing activation and bonding of bonding surfaces in vacuum, it is made possible to bond the second electrode 120f of the first circuit substrate 120 and the second bonding bump 130a of the second circuit substrate 130 without re-oxidation, which enables to form a highly reliable bonding.

The second bonding bump 130a has ductility and its surface follows the surface roughness of the second electrode 120f, which contributes to obtain a stable bonding condition.

The bonding may be performed at room temperature or at a low temperature of 100 °C or less, which contributes to reduce an impact (effect) of heating on characteristics of the quantum circuit 110a and misalignment during mounting caused by thermal expansion of a member to enable to perform accurate mounting.

In the example described with reference to FIG. 5 and FIG. 6, an example of a three-dimensional mounting package in which one first circuit substrate (interposer) 120, on which the quantum device 110 is mounted, is, for example, bonded to the second circuit substrate (package substrate) 130. The following describes other examples of a three-dimensional mounting package provided with a plurality of circuit substrates, each of which includes the quantum device 110 and the first circuit substrate (interposer) 120.

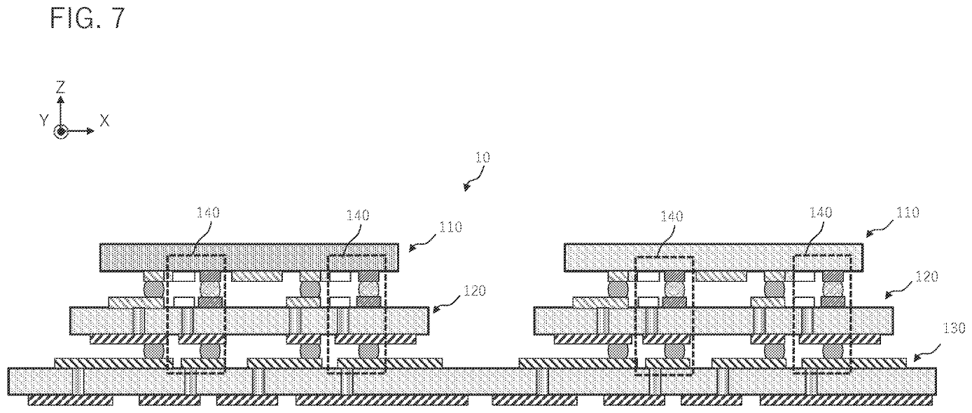

FIG. 7 is a schematic cross-sectional view schematically illustrating a cross-section of the variation of a superconducting circuit apparatus 10. In the example described with reference to FIG. 5, one first circuit substrate 120, on which the quantum device 110 is mounted, is mounted on the second circuit substrate 130. In an example illustrated in FIG. 7, a plurality of first circuit substrates 120, on each of which the quantum device 110 is mounted, are mounted on the second circuit substrate 130.

Configuration and materials of the quantum device 110, the second circuit substrate 130, and the first circuit substrate 120 are the same as those in the example described with reference to FIG. 5 and FIG. 6. In FIG. 7,
a bonding section (second bonding bump) between the second circuit substrate 130 and the first circuit substrate 120;
a through via of the first circuit substrate 120; and
a transmission section between the first circuit substrate 120 and the quantum device 110, of each transmission circuit section 140, are unified in a layout among a plurality of transmission circuit sections 140, respectively.

A bonding section (e.g., the dummy bump 120d in FIG. 5) between the first circuit substrate 120 and the quantum device 110 are disposed directly above the bonding section between the second circuit substrate 130 and the first circuit substrate 120.

Besides the transmission circuit section 140 to the non-contact coupling circuit of the quantum device 110, as described with reference to FIG. 5, regarding the transmission circuit section including: a bonding section (second bonding bump) between the second circuit substrate 130 and the first circuit substrate 120; a through via of the first circuit substrate; and a bonding section (first bonding bump) between the first circuit substrate 120 and the quantum device 110,
the bonding section (second bonding bump) between the second circuit substrate 130 and the first circuit substrate 120,
the through via of the first circuit substrate; and
the bonding section (first bonding bump) between the first circuit substrate 120 and the quantum device 110, in each transmission circuit section, are unified in a layout among transmission circuit sections.

According to a variation illustrated in FIG. 7, quantum circuits 110a that could not be aggregated into a single quantum device 110 can be distributed to a plurality of quantum devices 110. Therefore, it is possible to increase the number of qubits in a superconducting circuit apparatus.

In the above examples of the disclosure, an example of a three-dimensional mounting package in which, for example, one first circuit substrate (interposer) 120, on which the quantum device 110 is mounted, is bonded to the second circuit substrate 130 is described. In the following, further variations of three-dimensional mounting packages provided with a plurality of circuit substrates including the quantum device 110 and the first circuit substrate (interposer) 120 are described.

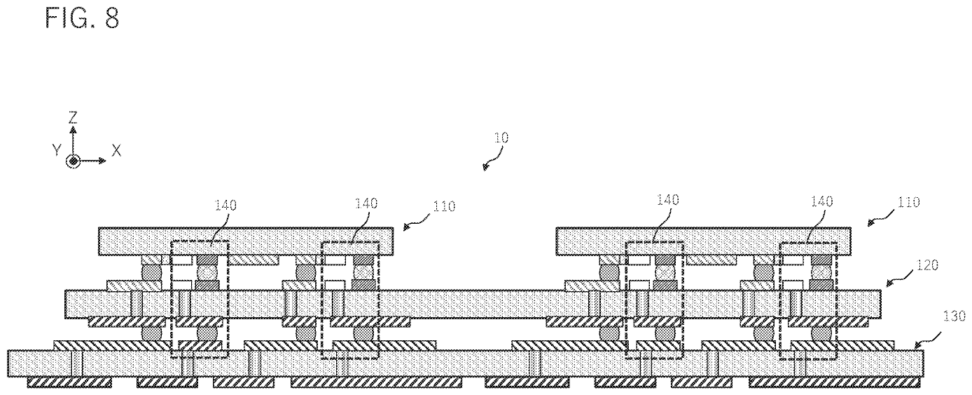

FIG. 8 is a schematic cross-sectional view illustrating a further variation of a superconducting circuit apparatus 10. In the example described with reference to FIG. 6 and FIG. 7, one quantum device 110 is mounted on the first circuit substrate 120. In the example illustrated in FIG. 8, a plurality of quantum devices 110 are mounted on the first circuit substrate 120. Configuration and materials of the first circuit substrate 120, the second circuit substrate 130, and the quantum device 110, which is not described above, are the same as in the examples described with reference to FIG. 5 to FIG. 7.

With this structure, quantum circuits 110a that could not be aggregated into a single quantum device 110 can be decentralized and arranged to a plurality of quantum devices 110. Therefore, it is possible to increase the number of bits in the superconducting circuit apparatus 10.

In a three-dimensional mounting package provided with a plurality of circuit substrates, each of which includes the quantum device 110 and the first wiring substrate (interposer) 120, it is suitable for a superconducting circuit apparatus that electrically bonds the first circuit substrate 120 and the second circuit substrate 130, which receives and/or outputs external signals to/from the non-contact coupling circuit 110b between the first circuit substrate 120 and the quantum device 110.

The disclosure of PTL 1 is incorporated herein by reference thereto. Variations and adjustments of the examples are possible within the scope of the overall disclosure (including the claims) based on the basic technical concept. Various combinations and selections of examples and disclosed elements (including the elements in each of the claims, examples, drawings, etc.) are possible within the scope of the claims of the present application. That is, the present disclosure includes various variations and modifications that could be made by those skilled in the art according to the overall disclosure including the claims and the technical concept.

What is claimed is:

1. A superconducting circuit apparatus comprising:
a second circuit substrate;
a first circuit substrate mounted on the second circuit substrate; and
a quantum device mounted on the first circuit substrate, the quantum device including a non-contact coupling circuit,
wherein the first circuit substrate includes:
a non-contact coupling circuit transmission part arranged spaced apart from and opposed to the non-contact coupling circuit of the quantum device; and
a through via penetrating through the first circuit substrate,
wherein the superconducting circuit apparatus includes
a plurality of first transmission circuit sections, each first transmission circuit section receiving and/or outputting a signal from the second circuit substrate to the quantum device, each first transmission circuit section including:
a first bonding section at which the second circuit substrate and the first circuit substrate are bonded together;
the through via penetrating through the first circuit substrate;
the non-contact coupling circuit of the quantum device; and
the non-contact coupling circuit transmission part of the first circuit substrate,
wherein the first bonding section, the through via, the non-contact coupling circuit, and the non-contact coupling circuit transmission part, in each first transmission circuit section, are unified in a layout among the plurality of first transmission circuit sections, respectively.

2. The superconducting circuit apparatus according to claim 1, comprising
a second bonding section between the first circuit substrate and the quantum device, disposed directly above the first bonding section between the second circuit substrate and the first circuit substrate.

3. The superconducting circuit apparatus according to claim 1, comprising
a second bonding section between the first circuit substrate and the quantum device,
wherein a second transmission circuit section for receiving and/or outputting a signal from the second circuit substrate to the quantum device includes:
the first bonding section between the second circuit substrate and the first circuit substrate;
the through via of the first circuit substrate, and
the second bonding section between the first circuit substrate and the quantum device, and
wherein the first bonding section, the through via and the second bonding section in each second transmission circuit section are unified in a layout among the plurality of second transmission circuit sections, respectively.

4. The superconducting circuit apparatus according to claim 2, wherein the second bonding section between the first circuit substrate and the quantum device, which is disposed directly above the first bonding section between the second circuit substrate and the first circuit substrate, is arranged as a floating island isolated from other wiring and circuits in at least one of the first circuit substrate and the second circuit substrate.

5. The superconducting circuit apparatus according to claim 2, wherein the second bonding section between the first circuit substrate and the quantum device, which is disposed directly above the first bonding section between the second circuit substrate and the first circuit substrate, is connected to a ground circuit arranged on at least one of the first circuit substrate and the second circuit substrate.

6. The superconducting circuit apparatus according to claim 1, comprising
a second bonding bump that configures the first bonding section between the second circuit substrate and the first circuit substrate,
wherein the second bonding bump includes
a material that has a melting point a lower than a first bonding bump that configures the second bonding section between the first circuit substrate and the quantum device, and ductility higher than or equivalent to the first bonding bump.

7. The superconducting circuit apparatus according to claim 1, wherein the non-contact coupling circuit transmission part of the first circuit substrate includes a capacitive coupling circuit for non-contact capacitive coupling with the non-contact coupling circuit of the quantum device to receive and/or output a signal.

8. The superconducting circuit apparatus according to claim 1, wherein the non-contact coupling circuit transmission part of the first circuit substrate includes an inductive coupling circuit for non-contact inductive coupling with the non-contact coupling circuit of the quantum device to receive and/or output a signal.

9. The superconducting circuit apparatus according to claim 1, wherein a plurality of the first circuit substrates are mounted on the second circuit substrate.

10. The superconducting circuit apparatus according to claim 1, wherein a plurality of the quantum devices are mounted on the first circuit substrate.

11. A fabrication method of a superconducting circuit apparatus comprising:
a second circuit substrate;
a first circuit substrate mounted on the second circuit substrate; and
a quantum device mounted on the first circuit substrate, the quantum device including a non-contact coupling circuit,
wherein the first circuit substrate includes:
a non-contact coupling circuit transmission part arranged spaced apart from and opposed to the non-contact coupling circuit of the quantum device; and
a through via penetrating through the first circuit substrate,
wherein the superconducting circuit apparatus includes
a plurality of first transmission circuit sections, each receiving and/or outputting a signal from the second circuit substrate to the quantum device, each first transmission circuit section including:
a first bonding section at which the second circuit substrate and the first circuit substrate are bonded together;
the through via penetrating through the first circuit substrate;
the non-contact coupling circuit of the quantum device; and
the non-contact coupling circuit transmission part of the first circuit substrate,
wherein the first bonding section, the through via, the non-contact coupling circuit, and the non-contact coupling circuit transmission part in each first transmission circuit section, are unified in a layout among the plurality of first transmission circuit sections, respectively, the method comprising:
placing the second circuit substrate and the first circuit substrate on which the quantum device is mounted in a chamber, such that a second bonding bump that is arranged on the second circuit substrate and configures the first bonding section, and a second electrode arranged on the first circuit substrate are arranged in a direction that a bonding face of the second bonding bump and a bonding face of the second electrode faces each other, and performing evacuation;
activating a surface of the bonding face of the second bonding bump arranged on the second circuit substrate and the second electrode arranged on the first circuit substrate;
performing a position alignment with the second bonding bump arranged on the second circuit substrate and the second electrode arranged on the first circuit substrate,
bringing the second bonding bump into contact with the second electrode to be pressurized in a room temperature or a low temperature not more than a predetermined temperature, with a vacuum, or
bringing the second bonding bump into contact with the second electrode to be pressurized with ultrasonic waves applied at a low temperature under atmospheric condition.

12. The fabrication method according to claim 11, wherein the second bonding bump includes
a material that has a melting point a lower than a first bonding bump that configures the second bonding section between the first circuit substrate and the quantum device, and ductility higher than or equivalent to the first bonding bump.

13. The fabrication method according to claim 11, further comprising
mounting a plurality of the quantum devices on the first circuit substrate.

14. The fabrication method according to claim 11, further comprising mounting a plurality of the first circuit substrate on the second circuit substrate.
